(19) United States
(12) Patent Application Publication
(10) Pub. No.: US 2016/0247788 A1
(43) Pub. Date: Aug. 25, 2016

(54) HIGH-VOLTAGE LIGHT EMITTING DIODE AND MANUFACTURING METHOD THEREOF

(71) Applicant: Genesis Photonics Inc., Tainan City (TW)

(72) Inventors: Tsung-Syun Huang, Tainan City (TW); Chih-Chung Kuo, Tainan City (TW); Yi-Ru Huang, Tainan City (TW); Chih-Ming Shen, Tainan City (TW); Kuan-Chieh Huang, New Taipei City (TW); Jing-En Huang, Tainan City (TW)

(21) Appl. No.: 15/045,426

(22) Filed: Feb. 17, 2016

Related U.S. Application Data
(60) Provisional application No. 62/116,923, filed on Feb. 17, 2015.

(51) Int. Cl. H01L 25/075; H01L 33/54; H01L 33/58; H01L 33/00; H01L 33/20; H01L 33/42; H01L 33/62

(52) U.S. Cl. CPC H01L 25/0753; H01L 33/42; H01L 33/54; H01L 33/62; H01L 33/0095; H01L 33/20; H01L 33/58; H01L 2933/0016

(57) ABSTRACT

The disclosure relates to a high-voltage light-emitting diode (HV LED) and a manufacturing method thereof. A plurality of LED dies connected in series, in parallel, or in series and parallel are formed on a substrate. A side surface of the first semiconductor layer of part of the LED dies is aligned with a side surface of the substrate, such that no space for exposing the substrate is reserved between the LED dies and the edges of the substrate, the ratio of the substrate being covered by the LED dies is increased, that is, light-emitting area per unit area is increased, and the efficiency of light extraction of HV LED is improved.

This application claims the benefit of U.S. provisional application Ser. No. 62/116,923, filed Feb. 17, 2015, the disclosure of which is incorporated by reference herein in its entirety.

### TECHNICAL FIELD

The disclosure relates in general to a light-emitting diode (LED) and a manufacturing method thereof, and more particularly to a high-voltage light-emitting diode (HV LED), which increases the efficiency of light extraction by increasing the ratio of lighting area through structural design, and a manufacturing method thereof.

### BACKGROUND

Light-emitting diode (LED) is a solid-state light-emitting element formed of a semiconductor material. In recent years, due to the advance in technology and the needs for power saving, the scope of application of LED has become wider and wider. As the application of LED is upgraded, the development of LED is directed towards larger power and higher luminance.

Of the various types of LEDs, the efficiency of high-voltage light-emitting diode (HV LED) is superior to that of conventional low-voltage light-emitting diode (LV LED) because the HV LED having the design of small current and multi-dies can uniformly diffuse the current to increase the efficiency of light extraction.

In the structure of conventional HV LED, a plurality of serially connected LED dies are disposed on a substrate, and the LED dies, each being surrounded by an electrically isolated region, are independent and are electrically connected through metal wires. The area of the electrically isolated regions is closely related to the efficiency of light extraction of HV LED, and the larger the area of the electrically isolated regions, the smaller the effective light emitting area. Therefore, conventional technology reduces wire width using high aspect ratio manufacturing process to increase the efficiency of light extraction.

### SUMMARY

According to one embodiment, a high-voltage light-emitting diode (HV LED) is provided. A plurality of LED dies are disposed on a substrate, a side surface of the LED dies on the periphery is aligned with a side surface of the substrate, an electrically isolated region is reserved between two adjacent LED dies, and the surface of the substrate is exposed in the electrically isolated region. In other words, the ratio of the substrate being exposed per unit area of the HV LED is reduced, such that the ratio of the substrate being covered by the LED dies is increased, the light-emitting area per unit area is increased, and the efficiency of light extraction of HV LED is improved.

According to another embodiment, a method for manufacturing an HV LED is provided. Based on conventional manufacturing process of LED, the ratio of the substrate being exposed per unit area is reduced to achieve above structural features and increase the efficiency of light extraction as long as the pattern of the epitaxial layer of the LED dies can be controlled using lithography process. The manufacturing method of the disclosure is compactable with conventional manufacturing processes of HV LED.

Therefore, the disclosure discloses an HV LED including a substrate and a plurality of LED dies. The LED dies are disposed on a surface of the substrate and connected in series, in parallel, or in series and parallel. Each of the LED dies includes a first semiconductor layer, a light-emitting layer and a second semiconductor layer stacked in sequence, wherein at least one first side surface of part of the first semiconductor layer on the cut surface of the HV LED is aligned with a side surface of the substrate. The side surface of the light-emitting layer and the second semiconductor layer is not aligned with the first side surface. At least one second side surface intersecting the first side surface is opposite to an adjacent LED diode.

The disclosed method for manufacturing LED includes following steps. An epitaxial layer is grown on a substrate, wherein the epitaxial layer has a first semiconductor layer, a light-emitting layer and a second semiconductor layer stacked in sequence. The epitaxial layer is etched using a lithography pattern to form a plurality of light-emitting units, wherein the lithography pattern includes a plurality of annular patterns, the part of the epitaxial layer corresponding to the annular patterns is partly removed for exposing the first semiconductor layer, the light-emitting units are connected through the exposed first semiconductor layer, and the epitaxial layer interposed between the annular patterns is partly removed for exposing the substrate. The first semiconductor layer and the substrate are cut along at least one cutting line for separating the light-emitting units to form a plurality of HV LEDs, wherein the cutting line passes through the first semiconductor layer interposed between the light-emitting units but does not pass through the light-emitting layer or the second semiconductor layer, such that at least one first side surface of the first semiconductor layer becomes part of a cut surface, and at least one first side surface of part of the first semiconductor layer on the cut surface of the HV LED is aligned with a side surface of the substrate.

Through the above structure of HV LED and method for manufacturing the same, LED with superior efficiency of light extraction can be effectively implemented.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of the structure of an HV LED according to an exemplary embodiment of the disclosure.

FIGS. 2A-2D are schematic diagrams of a flowchart of a method for manufacturing an HV LED according to an exemplary embodiment of the disclosure;

FIG. 3A is a top view of the structure of an HV LED showing that the distribution of the structure of the light-emitting unit on the substrate before the light-emitting unit is cut and the position of the cutting line according to another exemplary embodiment of the disclosure;

FIG. 3B is a top view of the structure of an HV LED showing that the LED dies included in a single light-emitting unit are aligned with the edges of the substrate after cutting according to another exemplary embodiment of the disclosure;

FIG. 4 is a side view of the structure of an HV LED showing the position of the first exposed region and the second exposed region according to an alternate exemplary embodiment of the disclosure, wherein the electrode region is not overlapped with the position of the cutting line; and

FIG. 5 is a schematic diagram of an HV LED according to another alternate exemplary embodiment of the disclosure, wherein the HV LEDs are connected in series through the insulating layer and the metal wire.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

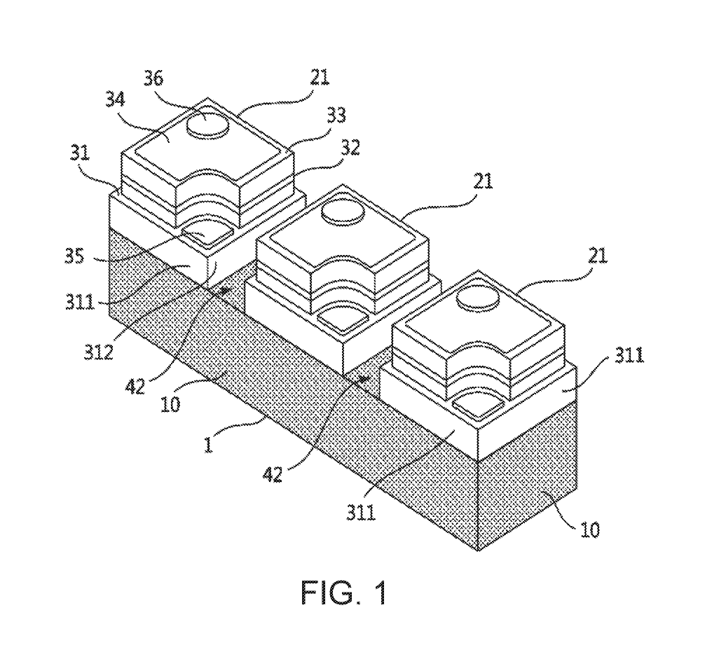

Referring to FIG. 1, a schematic diagram of the structure of an HV LED according to an exemplary embodiment of the disclosure is shown. The structure of the HV LED according to an exemplary embodiment of the disclosure includes a substrate 1 and a plurality of LED dies 21. Each LED die 21 includes a first semiconductor layer 31, a light-emitting layer 32, a second semiconductor layer 33 and a transparent conductive layer 34 stacked in sequence. The first semiconductor layer 31 has at least one first side surface 311 and at least one second side surface 312 intersecting the first side surface 311. Of the two side surfaces, the first side surface 311 is aligned with a side surface 10 of the substrate 1, and the second side surface 312 is opposite to an adjacent LED die 21.

Furthermore, in the structure of each LED die 21, only the first side surface 311 of the first semiconductor layer 31 is aligned with the side surface 10 of the substrate 1; the side surfaces of the light-emitting layer 32 and the second semiconductor layer 33, being indented due to the epitaxial structure, are not be aligned with the first side surface 311 or the side surface 10 of the substrate 1. Through the structural feature, a trench is formed between adjacent LED dies 21, the top surface of the substrate 1 is exposed only between adjacent LED dies 21, and the exposed areas are used as trenches which separate the LED dies into independent LED dies, such that the LED dies 21 are electrically separated from each other. Since the part of the high-voltage light-emitting diode (HV LED) close to the edge does not need to be electrically separated, the LED dies 21 will cover the surface of the part of the high-voltage light-emitting diode (HV LED) close to the edge as much as possible, such that the light-emitting area of the HV LED can be increased.

The structure of each LED die 21 further includes a first electrode 35 and a second electrode 36 electrically connected to the transparent conductive layer 34 disposed on the first semiconductor layer 31 and the second semiconductor layer 33, respectively.

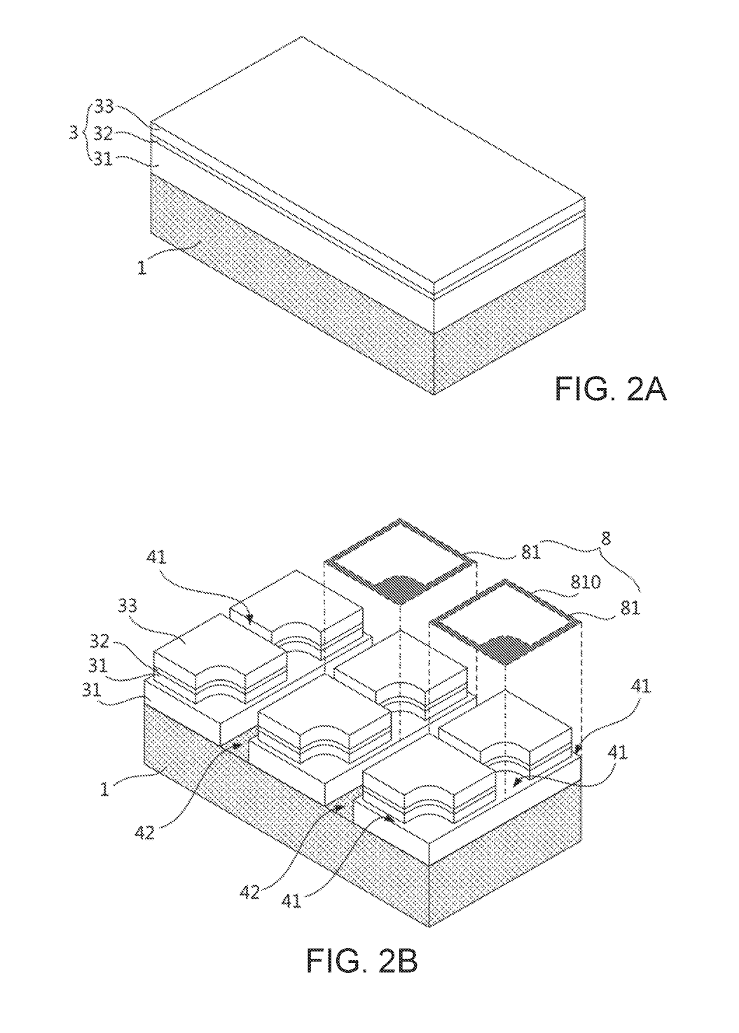

Referring to FIGS. 2A-2D, the method for manufacturing an HV LED disclosed in the disclosure includes following steps:

In step S1: an epitaxial layer is grown on a substrate, wherein the epitaxial layer has a first semiconductor layer, a light-emitting layer and a second semiconductor layer stacked in sequence;

In step S2: the epitaxial layer is etched using a lithography pattern to form a plurality of light-emitting units, wherein the lithography pattern comprises a plurality of annular patterns, the part of the epitaxial layer corresponding to the annular patterns is partly removed for exposing the first semiconductor layer, the light-emitting units are connected through the exposed first semiconductor layer, and the epitaxial layer interposed between the annular patterns is partly removed for exposing the substrate; and

In step S3: the first semiconductor layer and the substrate are cut along at least one cutting line for separating the light-emitting units to form a plurality of HV LEDs, wherein the cutting line passes through the first semiconductor layer interposed between the light-emitting units but does not pass through the light-emitting layer or the second semiconductor layer, such that at least one first side surface of the first semiconductor layer becomes part of a cut surface, and at least one first side surface of part of the first semiconductor layer on the cut surface of the HV LED is aligned with a side surface of the substrate.

In the disclosed step as indicated in FIGS. 2A and 2B, the first semiconductor layer 31, the light-emitting layer 32 and the second semiconductor layer 33 are formed on a sapphire substrate 1 by way of epitaxial growth, and part of the first semiconductor layer 31, the light-emitting layer 32 and the second semiconductor layer 33 is removed using an etching process. Through the operation, as indicated in FIG. 2B, the top surface of part of the first semiconductor layer 31 will be exposed to form a first exposed region 41, and the top surface of part of the substrate 1 will be exposed to form a second exposed region 42. The second exposed region 42 is formed by completely removing the first semiconductor layer 31 within the corresponding region. Therefore, step S2 is accompanied with a lithography pattern 8 having a plurality of annular patterns 81 for producing different etching results on the entire structure of the epitaxial layer 3.

Furthermore, in the present exemplary embodiment, the outer edges 810 of each annular pattern 81 define the scope of an LED die and are aligned with the edges of the first semiconductor layer 31 of the LED die. In other words, through the application of the lithography pattern 8, the epitaxial layer 3, which was originally complete, forms a plurality of light-emitting units, and the scope of each light-emitting unit includes a plurality of LED dies connected through the exposed first semiconductor layer 31. That is, the LED dies share the first exposed region 41.

In step S3, the first semiconductor layer 31 and the substrate 1 are cut along at least one cutting line 5 for separating the light-emitting units into independent units. In the embodiment disclosed in FIG. 2C and FIG. 2D, the substrate 1 carrying 6 LED dies 21 is cut along the cutting line 5 to form two light-emitting units 2, that is, two HV LEDs, and each HV LED has 3 LED dies 21. Since part of the first side surface 311 of the first semiconductor layer 31 of the LED dies 21 disposed on the substrate 1 is aligned with the cut surface 51 of the substrate 1 and the other first side surface 311 is aligned with the side surface 10 of the substrate 1, the LED dies 21 cover the surface of the substrate 1 as much as possible and only the second exposed region 42 is reserved for electrical separation.

In the present exemplary embodiment of the disclosure, the cutting line 5 passes through the first semiconductor layer 31 interposed between the light-emitting units but does not pass through the light-emitting layer 32 or the second semiconductor layer 33, such that at least one first side surface 311 of the first semiconductor layer 31 becomes part of the cut surface 51. In other words, the cutting line 5 extends along part of the edges of the LED dies defined by the lithography pattern 8, such that the HV LED only reserves the electrically isolated region between any two adjacent LED dies 21 and there is no need to reserve space on the peripheral of HV LED for exposing the surface of the substrate 1.

The present exemplary embodiment of the disclosure further includes step S3-1 prior to the step of cutting the first semiconductor layer and the substrate. In step S3-1, a plurality of first electrodes and a plurality of second electrodes are grown, such that the first electrodes and the second electrodes are electrically connected to the first semiconductor layer and a transparent conductive layer disposed on the second semiconductor layer, respectively. Through step S3-1, each LED die includes a first electrode 35 and a second electrode 36 respectively as indicated in FIG. 2C.

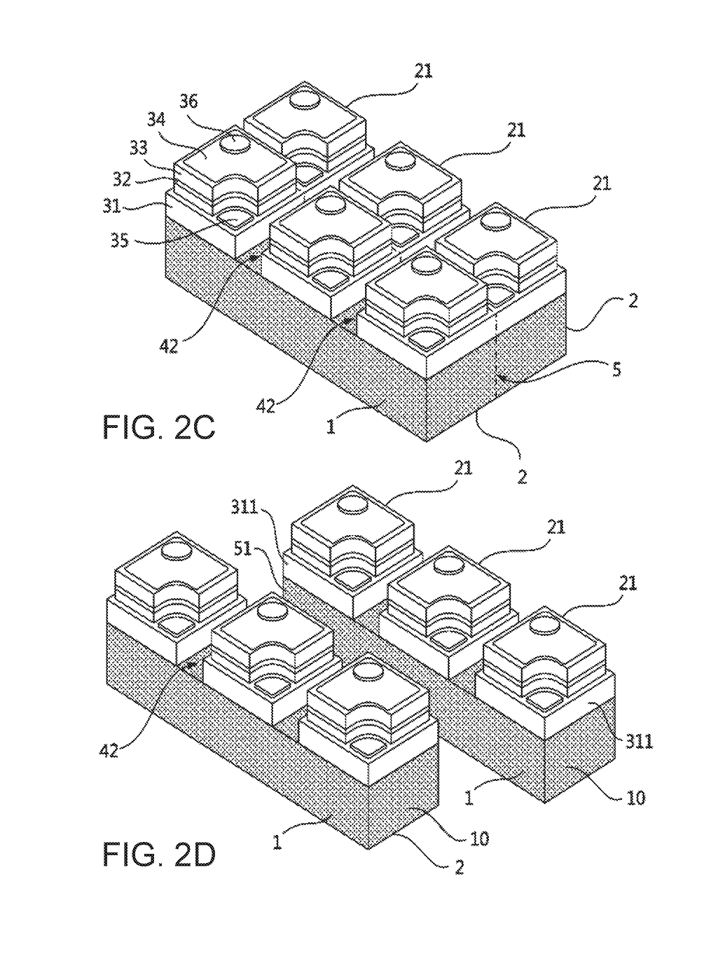

Referring to FIG. 3A, another exemplary embodiment of the disclosure is disclosed. Through the design of lithography pattern, the LED dies on the substrate 1 can have different arrangements or combinations. For example, 36 LED dies are disposed on the substrate 1 and can be divided into 9 groups of light-emitting units. The first semiconductor layer and the substrate can be cut along a plurality of cutting lines 5 for separating 9 light-emitting units to form 9 HV LEDs. FIG. 3B shows a light-emitting unit 2 obtained after cutting. As indicated in FIG. 3B, the light-emitting unit 2 includes 4 LED dies 21. A trench is formed between adjacent LED dies 21 on the surface of the substrate 1. The surface of the substrate is exposed and has a large lighting area, and there is no surrounding exposure near the peripheral of the light-emitting unit 2. In the disclosure, the quantity of LED dies included in a light-emitting unit (HV LED) is not limited to specific restrictions. The quantity of LED dies included in a light-emitting unit can be designed or adjusted according to the required voltage of related products.

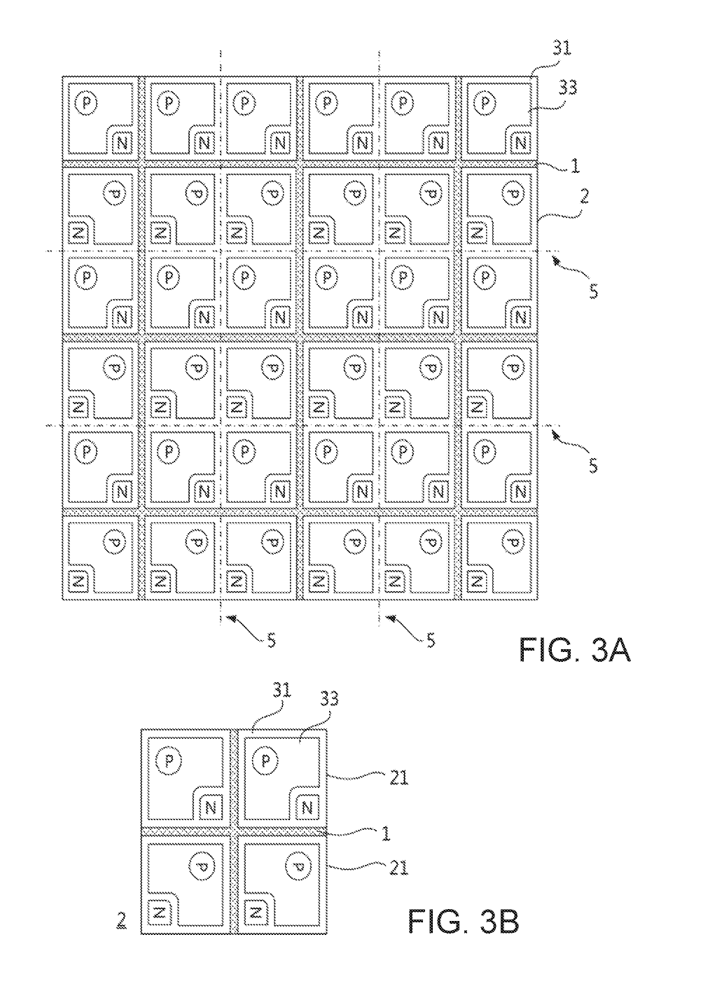

Referring to FIG. 4, a side view of the structure of an HV LED according to an alternate exemplary embodiment of the disclosure is shown. As indicated in the side view of an un-cut HV LED, the exposed first semiconductor layer 21 includes at least one electrode region 410 in which the first electrode 35 is disposed. The electrode region 410 is not overlapped with the cutting line 5, and will not be affected by the cutting step.

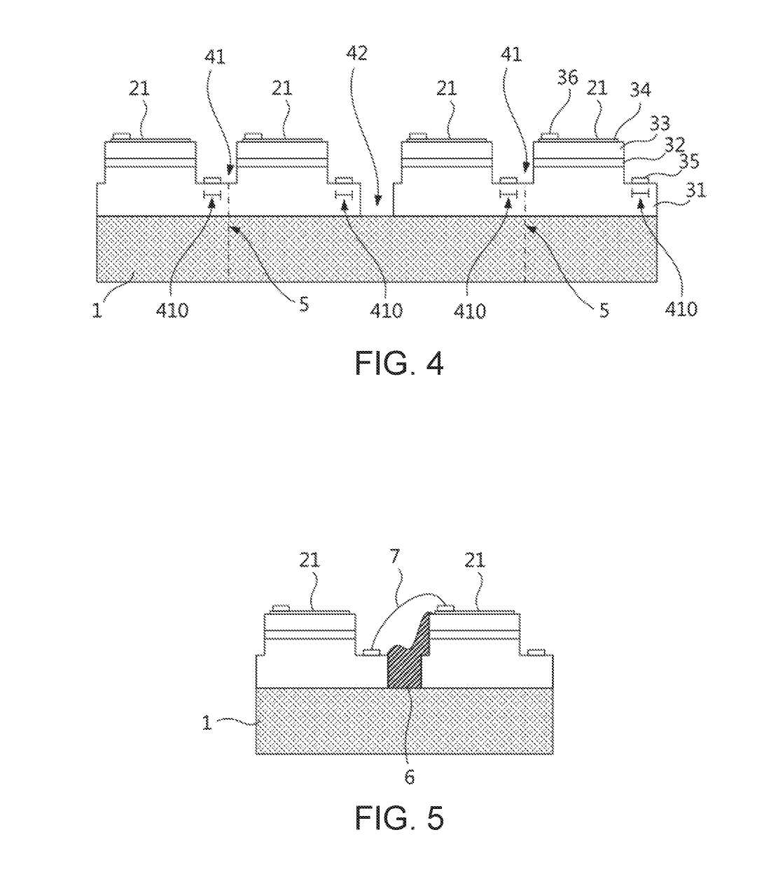

Referring to FIG. 5, a schematic diagram of an HV LED according to another alternate exemplary embodiment of the disclosure is shown. An insulating layer 6, formed of an insulating material, can be interposed in the electrically isolated region (such as the second exposed region 42) between adjacent LED dies 21. The LED dies 21 are electrically connected through the metal wire 7, and are connected in series to form an HV LED.

The disclosure discloses an HV LED and a manufacturing method thereof. The ratio of the substrate being exposed in the HV LED is reduced, that is, the ratio of the substrate being covered by the LED grains is increased, such that the light-emitting area per unit area is increased, and the efficiency of light extraction of HV LED is improved. While improving the efficiency of light extraction, the disclosure can change the distribution of LED dies on the substrate by adjusting and controlling the lithography process without adding too much load to the manufacturing process. To summarize, the disclosure indeed is an HV LED having high application value and a manufacturing method thereof.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A high-voltage light-emitting diode (HV LED), comprising:
a substrate; and
a plurality of LED dies disposed on a surface of the substrate and connected in series, wherein each of the LED dies comprises a first semiconductor layer, a light-emitting layer and a second semiconductor layer stacked in sequence, at least one first side surface of part of the first semiconductor layer is aligned with a side surface of the substrate, at least one second side surface intersecting the first side surface is opposite to an adjacent LED die, and a trench is formed between the LED dies to expose the surface of the substrate.

2. The HV LED according to claim 1, wherein the LED dies further comprise a first electrode and a second electrode electrically connected to the first semiconductor layer and the second semiconductor layer, respectively.

3. The HV LED according to claim 1, wherein the LED dies further comprise a transparent conductive layer interposed between the second semiconductor layer and the second electrode.

4. The HV LED according to claim 1, wherein an insulating layer is interposed between the LED dies.

5. The HV LED according to claim 1, wherein the LED dies disposed on the surface of the substrate can further be electrically connected in series, in parallel, or in series and in parallel.

6. The HV LED according to claim 1, wherein the first side surface of part of the first semiconductor layer on a cut surface of the HV LED is aligned with the side surface of the substrate.

7. A method for manufacturing an HV LED, comprising:
growing an epitaxial layer on a substrate, wherein the epitaxial layer comprises a first semiconductor layer, a light-emitting layer and a second semiconductor layer stacked in sequence;
etching the epitaxial layer using a lithography pattern to form a plurality of light-emitting units, wherein the lithography pattern comprises a plurality of annular patterns, a part of the epitaxial layer corresponding to the annular patterns is partly removed for exposing the first semiconductor layer, the light-emitting units are connected through the first semiconductor layer being exposed, and the epitaxial layer interposed between the annular patterns is partly removed for exposing the substrate; and
cutting the first semiconductor layer and the substrate along at least one cutting line for separating the light-emitting units to form a plurality of HV LEDs, wherein the cutting line passes through the first semiconductor layer interposed between the light-emitting units but does not pass through the light-emitting layer or the second semiconductor layer, such that at least one first side surface of the first semiconductor layer becomes part of a cut surface.

8. The method according to claim 7, wherein prior to the step of cutting the first semiconductor layer and the substrate according to the cutting line, the method further comprises:
growing a plurality of first electrodes and a plurality of second electrodes, such that the first electrodes and the second electrodes are electrically connected to the first semiconductor layer and the transparent conductive layer disposed on the second semiconductor layer, respectively.

9. The method according to claim 8, wherein the first semiconductor layer being exposed comprises at least one electrode region in which the first electrodes are disposed, and the electrode region is not overlapped with the position of the cutting line.

10. The method according to claim 7, wherein outer edges of the annular patterns define a scope of an LED grain.
